(19) United States
(12) Patent Application Publication
(10) Pub. No.: US 2018/0151749 A1
(43) Pub. Date: May 31, 2018

(54) Thin Film Transistor, Array Substrate and Methods for Manufacturing and Driving the same and Display Device

(71) Applicants: BOE Technology Group Co., Ltd., Beijing (CN); Hefei Xinsheng Optoelectronics Technology Co., Ltd., Anhui (CN)

(72) Inventors: Miao Zhang, Beijing (CN); Jing Sun, Beijing (CN)

(21) Appl. No.: 15/531,111

(22) PCT Filed: May 30, 2016
(86) PCT No.: PCT/CN2016/083905

§ 371 Date: May 26, 2017

(30) Foreign Application Priority Data
Mar. 14, 2016 (CN) 201610144790.X

(51) Int. Cl. H01L 29/786; G09G 3/36; H01L 27/12; H01L 29/24

(52) U.S. Cl. CPC H01L 29/78648; G09G 3/3648; H01L 27/1225; G02F 1/1368; H01L 27/127; H01L 29/24; H01L 29/7869; H01L 27/124

(57) ABSTRACT

Disclosed is a thin film transistor, an array substrate and method for manufacturing and driving the same, and a display device. The thin film transistor comprises an active layer formed by an oxide semiconductor material; a gate electrode insulated from the active layer; a source electrode in contact with the active layer; and a drain electrode in contact with the active layer, wherein the gate electrode comprises a first gate electrode below the active layer and a second gate electrode above the active layer.

### CROSS-REFERENCE TO RELATED APPLICATION

This application is a national phase application from PCT/CN2016/083905 filed on May 30, 2016 and claims the benefit of Chinese Patent Application No. CN201610144790.X, entitled “Thin Film Transistor, Array Substrate, Methods for Manufacturing and Driving the same and Display Device”, filed on Mar. 14, 2016 in the State Intellectual Property Office of China, the whole disclosure of which is incorporated herein by reference.

### BACKGROUND OF THE INVENTION

### Field of the Invention

Embodiments of the disclosure relate to field of display technique, in particular to a thin film transistor, an array substrate and methods for manufacturing and driving the same, and a display device.

### Description of the Related Art

With development of liquid crystal display technique, an oxide thin film transistor (TFT) of high mobility is used widely, thus becomes a new development trend. An amorphous silicon thin film transistor typically has a mobility of about 0.5 cm²/Vs. In a case where a liquid crystal display (LCD) has higher resolution and frequency, the mobility of the existing amorphous silicon thin film transistor hardly satisfies the relevant requirements. Although a low temperature polysilicon has higher mobility, it can not be compatible with the existing amorphous silicon product lines. An oxide TFT has higher mobility and good compatibility with the existing product lines, and can satisfy the increasing demands of display better.

However, during operation of a display panel, a gate electrode of the oxide thin film transistor is continuously applied with high and low level signals, which may cause electrons therein to be repelled or attracted, which in turn results in a shift of a threshold voltage (Vth) of the thin film transistor, and the shift of the threshold voltage may result in various unqualified displays.

### SUMMARY OF THE INVENTION

The disclosure is intended to at least solve the problem in which a shift of a threshold voltage (Vth) easily occurs because a gate electrode of an oxide thin film transistor (TFT) is continuously applied with high and low level signals during operation of a display panel.

In order to solve the above problem, embodiments of one aspect of the disclosure provide a thin film transistor comprising: an active layer; a gate electrode insulated from the active layer; a source electrode in contact with the active layer; and a drain electrode in contact with the active layer, wherein the gate electrode comprises a first gate electrode below the active layer and a second gate electrode above the active layer.

According to an exemplary embodiment of the disclosure, the first gate electrode is directly below the active layer, and the second gate electrode is directly above the active layer.

According to an exemplary embodiment of the disclosure, a material of the active layer comprises indium-gallium-zinc oxide.

Embodiments of another aspect of the disclosure provide an array substrate comprising the thin film transistor as described above.

In an exemplary embodiment of the disclosure, the array substrate further comprises: a first gate line electrically connected with the first gate electrode and a second gate line electrically connected with the second gate electrode; a gate insulation layer for insulating the first gate electrode from the active layer; a passivation layer for insulating the active layer from the second gate; and a transparent and electrically conductive layer above the passivation layer and serving as a common electrode layer or a pixel electrode layer.

According to an exemplary embodiment of the disclosure, the second gate electrode is made of the same material and disposed in the same layer as the transparent and electrically conductive layer.

According to an exemplary embodiment of the disclosure, the first gate electrode, the first gate line and the second gate line are made of the same material and disposed in the same layer.

In an exemplary embodiment of the disclosure, the first gate electrode, the first gate line and the second gate line are formed on a surface of the base substrate, the gate insulation layer is above the base substrate and covers the first gate electrode, the first gate line and the second gate line, and the active layer is above the gate insulation layer.

In an exemplary embodiment of the disclosure, the array substrate further comprises an etching stop layer above the gate insulation layer and covers the active layer, wherein the source electrode and the drain electrode are in contact with the active layer through a first via hole in the etching stop layer.

In an exemplary embodiment of the disclosure, the passivation layer is above the etching stop layer and covers the source electrode and drain electrode, the second gate electrode is formed on the passivation layer and electrically connected with the second gate line through a second via hole passing through the passivation layer, the etching stop layer and the gate insulation layer, and the transparent and electrically conductive layer is in contact and electrically connected with the drain electrode through a third via hole in the passivation layer.

Embodiments of another aspect of the disclosure provide a display device comprising the array substrate as described above.

Embodiments of another aspect of the disclosure provide a method for manufacturing an array substrate comprising a thin film transistor including an active layer, first and second gate electrodes insulated from the active layer, a source electrode in contact with the active layer and a drain electrode in contact with the active layer, the method comprising:

forming the first gate electrode below the active layer and the second gate electrode above the active layer.

In an exemplary embodiment of the disclosure, the method further comprises:

Forming a first gate line electrically connected with the first gate electrode and a second gate line electrically connected with the second gate electrode on a surface of a base substrate;

forming an gate insulation layer for insulating the first gate electrode from the active layer above the base substrate, such that the gate insulation layer covers the first gate electrode, the first gate line and the second gate line, and the active layer is above the gate insulation layer;

forming an etching stop layer having a first via hole above the gate insulation layer, such that the etching stop layer covers the active layer; and forming a source electrode and a drain electrode so that the source and drain electrodes are in contact with the active layer through the first via hole;

forming a passivation layer for insulating the active layer from the second gate electrode above the gate insulation layer, such that the passivation layer covers the source electrode and the drain electrode;

forming a transparent and electrically conductive layer serving as a common electrode layer or a pixel electrode layer above the passivation layer and forming the second electrode above the passivation layer, such that the second electrode is electrically connected with the second gate line through a second via hole passing through the passivation layer, the etching stop layer and the gate insulation layer, and the transparent and electrically conductive layer is in contact and connected with the drain electrode through a third via hole in the passivation layer.

According to an exemplary embodiment of the disclosure, the second gate electrode and the transparent and electrically conductive layer are simultaneously formed in a single patterning process.

According to an exemplary embodiment of the disclosure, the first gate electrode, the first gate line and the second gate line are simultaneously formed in a single patterning process.

Embodiments of another aspect of the disclosure provide a method for driving the array substrate as described above, comprising:

applying a gate signal to the first gate electrode of the thin film transistor and floating the second gate electrode during displaying a n^{th} frame of image, wherein n is a nonzero natural number; and

applying a gate signal to the second gate electrode of the thin film transistor and floating the first gate electrode during displaying a n+1^{th} frame of image.

### BRIEF DESCRIPTION OF THE DRAWINGS

FIG. 1 is a schematic view of a thin film transistor according to an exemplary embodiment of the disclosure;

FIG. 2 is a schematic view of an array substrate according to an exemplary embodiment of the disclosure; and

FIGS. 3 to 8 are schematic views showing a process for manufacturing an array substrate according to an exemplary embodiment of the disclosure.

### DETAILED DESCRIPTION OF PREFERRED EMBODIMENTS OF THE INVENTION

Implementations of the disclosure will be described below in detail with reference to the accompanying drawings and embodiments. The embodiments discussed below are illustrative, rather than limiting the scope of the disclosure. In addition, it should be understood by those skilled in the art that the terms “first”, “second”, “third” and the like in the disclosure are only used to distinguish components or structures, rather than referring to order of time or structure. Further, when it mentions that two or more components are “in the same layer” in the disclosure, it does not necessarily means that the two or more components are physically arranged in the same layer, but means that the two or more components are formed in the same patterning process.

Embodiments of the disclosure generally provide a thin film transistor comprising an active layer formed by an oxide semiconductor material, a gate electrode insulated from the active layer, a source electrode in contact with the active layer and a drain electrode in contact with the active layer, wherein the gate electrode comprises a first gate electrode located below the active layer and a second gate electrode located above the active layer.

With the thin film transistor according to embodiments of the disclosure, the gate electrode comprises the first gate electrode located below the active layer and the second gate electrode located above the active layer. Through alternatively controlling the first and second gate electrodes, it is possible to inhabit a shift of an electrical characteristic of the oxide thin film transistor such as a threshold voltage (Vth), so as to improve stability of switching characteristic thereof.

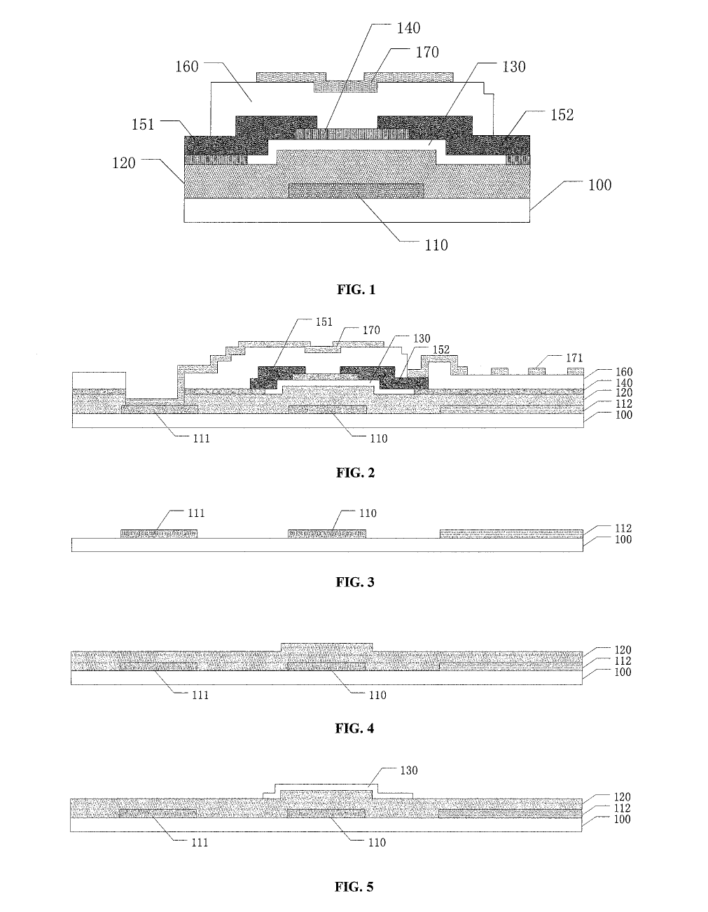

Referring to FIG. 1 showing a schematic view of a thin film transistor according to an exemplary embodiment of the disclosure, the thin film transistor comprises a first gate electrode 110 disposed on a base substrate 100, an active layer 130 formed by an oxide semiconductor material, a source electrode 151, a drain electrode 152 and a second gate electrode 170. The source electrode 151 and the drain electrode 152 are in contact with the active layer 130 through a first via hole formed in an etching stop layer 140.

The first gate electrode 110 is disposed below the active layer 130, for example, directly below the active layer 130. Between the first gate electrode 110 and the active layer 130, a gate insulation layer 120 is provided for insulating the first gate electrode 110 from the active layer 130. The second gate electrode 170 is disposed above the active layer 130, for example, directly above the active layer 130. The second gate electrode 170 is arranged opposite to the first gate electrode 110 in a top-bottom direction. Between the active layer 130 and the second gate electrode 170, a passivation layer 160 is provide for insulating the active layer 130 from the second gate electrode 170.

For example, the active layer 130 may be made of indium-gallium-zinc oxide.

In addition, embodiments of the disclosure further provide an array substrate comprising a thin film transistor including an active layer formed by an oxide semiconductor material, a gate electrode insulated from the active layer, a source electrode in contact with the active layer and a drain electrode in contact with the active layer, wherein the gate electrode comprises a first gate electrode located below the active layer and a second gate electrode located above the active layer

For example, the above array substrate may be an array substrate of a display panel having a display mode which is a horizontal electric field mode, such as a display panel of an ADS mode, an IPS mode or FFS mode. In addition to the above thin film transistor, the array substrate further comprises a first gate line electrically connected with the first gate electrode of the thin film transistor, a second gate line electrically connected with the second gate electrode of the thin film transistor, an insulating layer for insulating the first electrode and the active layer, a passivation layer for insulating the active layer and the second gate electrode, and a transparent and electrically conductive layer disposed above the passivation layer and serving as a common electrode layer or a pixel electrode layer.

Optionally, in order to reduce the number of the patterning steps of the array substrate, the second gate electrode is made of the same material and arranged in the same layer as the transparent and electrically conductive layer.

Optionally, in order to reduce the number of the patterning steps in manufacturing the array substrate, the first gate electrode, the first gate line and the second gate line are made of the same material and arranged in the same layer.

Referring to FIG. 2 showing a schematic view of an array substrate according to an exemplary embodiment of the disclosure, the array substrate comprises a base substrate 100 on which a thin film transistor is disposed. The thin film transistor comprises a first gate electrode 110, an active layer 130 formed by an oxide semiconductor material, a source electrode 151, a drain electrode 152 and a second gate electrode 170.

The source electrode 151 and the drain electrode 152 are in contact with the active layer 130 through a first via hole in an etching stop layer 140. The first gate electrode 110 is disposed below the active layer 130, for example, directly below the active layer 130. Between the first gate electrode 110 and the active layer 130, a gate insulation layer 120 is provided for insulating the first gate electrode 110 from the active layer 130. The second gate electrode 170 is disposed above the active layer 130, for example, directly above the active layer 130. Between the active layer 130 and the second gate electrode 170, a passivation layer 160 is provided for insulating the active layer 130 from the second gate electrode 170.

In addition, in an exemplary embodiment, as shown in FIG. 2, for example, the array substrate further comprises: a first gate line 113 electrically connected with the first gate electrode 110 and a second gate line 111 electrically connected with the second gate electrode 170. The first gate line is arranged in a straight line and electrically connected with the first gate electrode, and thus are not shown in the cross-sectional view in FIG. 2 for example. The second gate line 111 is parallel with the first gate line 113. The array substrate further comprises a common electrode layer 112 formed by a transparent electrically conductive material such as ITO; and a pixel electrode layer 171 formed by a transparent electrically conductive material.

The common electrode layer 112, the first gate electrode 110, the first gate line 113 and the second gate line 111 are disposed below the gate insulation layer 120. The pixel electrode layer 171 and the second gate electrode 170 are disposed above the passivation layer 160. The second gate electrode 170 is electrically connected with the second gate line 111 through a second via hole passing through the gate insulation layer 120, the etching stop layer 140 and the passivation layer 160.

Further, each of the common electrode layer 112, the first gate electrode 110, the first gate line 113 and the second gate line 111 may be made of the transparent electrically conductive material. The common electrode layer 112, the first gate electrode 110, the first gate line 113 and the second gate line 111 may be simultaneously formed in a single patterning process during manufacturing.

In addition, both the pixel electrode layer 171 and the second gate electrode 170 may also be made of the transparent electrically conductive material. The pixel electrode layer 171 and the second gate electrode 170 may be simultaneously formed in the single patterning process during manufacturing.

Note that, in some embodiments of the disclosure, the common electrode layer 112 is disposed below the gate insulation layer 120, and the pixel electrode layer 171 is disposed above the passivation layer 160. However, the disclosure is not limited herein. For example, in other embodiments, the pixel electrode layer may be disposed below the gate insulation layer, and the common electrode layer may be disposed above the passivation layer.

Embodiments of the disclosure further provide a display device comprising the array substrate as described above. The display device according to embodiments of the disclosure may include a display screen of a laptop, a liquid crystal display, a liquid crystal television, a digital camera, a mobile phone, a tablet computer and any other products or components having display function.

Embodiments of the disclosure further provide a method for manufacturing an array substrate comprising a thin film transistor including an active layer formed by an oxide semiconductor material, a first and second gate electrodes insulated from the active layer, a source electrode in contact with the active layer and a drain electrode in contact with the active layer, the method comprising:

forming the first gate electrode below the active layer and the second gate electrode above the active layer.

For example, the above array substrate may include an array substrate of a display panel having a display mode of a horizontal electric field mode such as a display panel of an ADS mode, an IPS mode or FFS mode. In addition to manufacturing the above thin film transistor, the method for manufacturing the array substrate further comprises:

forming a first gate line electrically connected with the first gate electrode and a second gate line electrically connected with the second gate electrode on a surface of a base substrate;

forming an gate insulation layer for insulating the first gate electrode from the active layer above the base substrate, such that the gate insulation layer covers the first gate electrode, the first gate line and the second gate line, and the active layer is formed above the gate insulation layer;

forming an etching stop layer having a first via hole on the gate insulation layer, such that the etching stop layer covers the active layer, and forming a source electrode and a drain electrode so that the source electrode and the drain electrode are in contact with the active layer through the first via hole;

forming a passivation layer for insulating the active layer from the second gate electrode above the gate insulation layer, such that the passivation layer covers the source electrode and the drain electrode;

forming a transparent and electrically conductive layer serving as a common electrode layer or a pixel electrode layer above the passivation layer and forming the second gate electrode above the passivation layer, such that the second electrode is electrically connected with the second gate line through a second via hole passing through the passivation layer, the etching stop layer and the insulation layer, and the transparent and electrically conductive layer is in contact and connected with the drain electrode through a third via hole in the passivation layer.

For example, in a specific embodiment, referring to FIGS. 3 to 8 in which the first gate line 113 is not shown for sake of simplicity (the first gate line 113 is described and shown in FIG. 2), the method for manufacturing the array substrate as described above may comprise:

S1: forming a common electrode layer, for example, sputtering an ITO thin film on a base substrate such as a glass substrate, then coating a photoresist layer, exposing the photoresist layer using a mask for making the common electrode layer, removing the remaining photoresist after development and etching processes, and finally forming a pattern of the common electrode layer;

S2: forming a first gate electrode, a first gate line and a second gate line, for example, it is possible to form the first gate electrode, the first gate line and the second gate line simultaneously in a single patterning process. Specifically, firstly performing a metal sputtering process, and then coating a photoresist layer, and exposing the photoresist layer by using a mask for forming a gate layer, peeling off the remaining photoresist after the development and etching processes, and finally forming a pattern including the first gate electrode, the first gate line and the second gate line, and a structure thereof is shown in FIG. 3 in which the common electrode layer 112, the first gate electrode 110, the first gate line and the second gate line are arranged on a base substrate 100;

S3: forming a gate insulation layer, for example, it is possible to deposit SiO₂ or SiONₓ by a chemical vapor deposition (CVD) process to form a gate insulation layer 120 as shown in FIG. 4;

S4: forming an active layer, for example, it is possible to form an oxide semiconductor film layer by using IGZO or other oxide semiconductor material through sputtering, then coating a photoresist layer, expose the photoresist layer by using a mask for making the active layer, and then peeling off the remaining photoresist after development and etching processes, thereby forming a pattern of the active layer 130 as shown in FIG. 5;

S5: forming an etching stop layer (ESL), for example, it is possible to deposit SiOx through a CVD process, then coating a photoresist layer by using a mask for making the etching stop layer, and then peeling off the remaining photoresist after development and etching processes, thereby forming a pattern of the etching stop layer 140 having a first via hole as shown in FIG. 6;

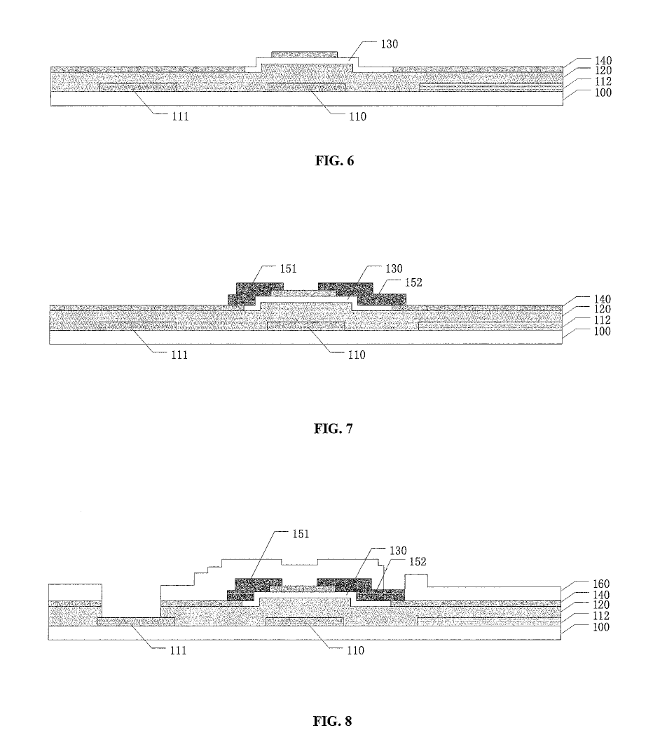

S6: forming a pattern of source and drain (SD) layer, for example, it is possible to deposit a metal thin film through a sputtering process, then coating a photoresist layer by using a mask for making the source and drain layer, and then peeling off the remaining photoresist after development and wet etching processes, thereby forming a pattern including a source electrode 151, a drain electrode 152 and data lines as shown in FIG. 7;

S7: forming a passivation (PVX) layer, for example, it is possible to deposit SiO₂ or SiONₓ through a CVD process, then coating a photoresist layer by using a mask for making the passivation layer, and then peeling off the remaining photoresist after development and etching processes, thereby forming via holes in the gate insulation layer 120, the etching stop layer 140 and the passivation layer 160, including a third via hole for connecting a subsequently formed pixel electrode layer with the drain electrode 152 of the thin film transistor and a second via hole for connecting a subsequently formed second gate electrode 170 with the second gate line 111, as shown in FIG. 8;

S8: forming a pixel electrode layer and a second gate electrode, for example, it is possible to form the pixel electrode layer and the second gate electrode simultaneously in a single patterning process. For example, firstly forming a layer of transparent electrically conductive thin film through a sputtering process, then forming an electrically conductive pattern including a slit-type pixel electrode (PXL) layer and the second gate electrode after coating photoresist, exposure, development, etching and peeling processes, in which the second gate electrode is electrically connected with the second gate line and the pixel electrode layer is electrically connected with the drain electrode through the via holes formed in the step of S7, thereby forming the array substrate as shown in FIG. 2.

Optionally, the common electrode layer, the first gate electrode, the first gate line and the second gate line may be patterned through a same half tone mask (HTM), so that the common electrode layer, the first gate electrode, the first gate line and the second gate line are simultaneously formed in the single patterning process, thereby reducing the number of the patterning processes.

The method for manufacturing the array substrate according to embodiments of the disclosure can effectively inhabit the shift of the threshold voltage (Vth) of the oxide thin film transistor, and will not add new masks in the process, effectively reduce the defects and improve product yield.

In addition, embodiments of the disclosure further provide a method for driving the above array substrate comprising:

applying a gate signal to the first gate electrode of the thin film transistor and floating the second gate electrode during displaying a n^{th} frame of image, wherein n is a nonzero natural number; and

applying a gate signal to the second gate electrode of the thin film transistor and floating the first gate electrode during displaying a n+1^{th} frame of image.

For example, when a display screen operates, the first gate lines are applied with a VGH/VGL signal and the second gate lines are floating during a frame of image of an odd number, and the second gate lines are applied with a VGH/VGL signal and the first gate lines are floating during the frame of image of an even number. Since the TFT of the array substrate has a symmetrical double-gate design in the top-to-bottom direction, and the two gate electrodes are arranged to be opposite to each other, the shift of the threshold Vth of the TFT is inhabited, thereby ensuring the stability of the electrical characteristic of the TFT.

The above implementations are illustrative, rather than limiting the disclosure. Those ordinary skilled in the art may make various changes and modifications without departing from the spirit and scope thereof. Therefore, all the equivalents should be also fall within the scope of the disclosure. The scope of the disclosure is solely defined by claims.

1. A thin film transistor comprising
an active layer formed by an oxide semiconductor material;
a gate electrode insulated from the active layer;
a source electrode in contact with the active layer; and
a drain electrode in contact with the active layer;
wherein the gate electrode comprises a first gate electrode below the active layer and a second gate electrode above the active layer.

2. The thin film transistor according to claim 1, wherein the first gate electrode is directly below the active layer, and the second gate electrode is directly above the active layer.

3. The thin film transistor according to claim 1, wherein the oxide semiconductor material comprises indium gallium zinc oxide.

4. An array substrate comprising the thin film transistor according to claim 1.

5. The array substrate according to claim 4, further comprising
a first gate line electrically connected with the first gate electrode and a second gate line electrically connected with the second gate electrode;
a gate insulation layer for insulating the first gate electrode from the active layer;
a passivation layer for insulating the active layer from the second gate electrode; and
a transparent and electrically conductive layer above the passivation layer and serving as a common electrode layer or a pixel electrode layer.

6. The array substrate according to claim 5, wherein the second gate electrode is made of the same material and disposed in the same layer as the transparent and electrically conductive layer.

7. The array substrate according to claim 5, wherein the first gate electrode, the first gate line and the second gate line are made of the same material and disposed in the same layer.

8. The array substrate according to claim 5, wherein the first gate electrode, the first gate line and the second gate lines are formed on a surface of a base substrate, the gate insulation layer is above the base substrate and covers the first gate electrode, the first gate line and the second gate line, and the active layer is above the gate insulation layer.

9. The array substrate according to claim 8, further comprising an etching stop layer above the gate insulation layer and covers the active layer, wherein the source electrode and the drain electrode are in contact with the active layer through a first via hole in the etching stop layer.

10. The array substrate according to claim 9, wherein the passivation layer is above the etching stop layer and covers the source electrode and drain electrode, the second gate electrode is above the passivation layer and electrically connected with the second gate line through a second via hole passing through the passivation layer, the etching stop layer and the gate insulation layer, and the transparent and electrically conductive layer is electrically connected with the drain electrode through a third via hole in the passivation layer.

11. A display device comprising the array substrate according to claim 4.

12. A method for manufacturing an array substrate comprising a thin film transistor including an active layer formed by an oxide semiconductor material, a first gate electrode and a second gate electrode insulated from the active layer, a source electrode in contact with the active layer and a drain electrode in contact with the active layer, the method comprising:
forming the first gate electrode below the active layer and forming the second gate electrode above the active layer.

13. The method according to claim 12, further comprising:
forming a first gate line electrically connected with the first gate electrode and a second gate line electrically connected with the second gate electrode on a surface of a base substrate;
forming an gate insulation layer for insulating the first gate electrode from the active layer above the base substrate, such that the gate insulation layer covers the first gate electrode, the first gate line and the second gate line, and the active layer is formed above the gate insulation layer;
forming an etching stop layer having a first via hole above the gate insulation layer such that the etching stop layer covers the active layer, and forming the source electrode and the drain electrode so that the source and drain electrodes are in contact with the active layer through the first via hole;
forming a passivation layer for insulating the active layer from the second gate electrode above the etching stop layer such that the passivation layer covers the source electrode and the drain electrode; and
forming a transparent and electrically conductive layer serving as a common electrode layer or a pixel electrode layer above the passivation layer and forming the second gate electrode above the passivation layer, such that the second gate electrode is electrically connected with the second gate line through a second via hole passing through the passivation layer, the etching stop layer and the insulation layer, and the transparent and electrically conductive layer is in contact and connected with the drain electrode through a third via hole in the passivation layer.

14. The method according to claim 13, wherein the second gate electrode and the transparent and electrically conductive layer are simultaneously formed in a single patterning process.

15. The method according to claim 13, wherein the first gate electrode, the first gate line and the second gate line are simultaneously formed in a single patterning process.

16. A method for driving the array substrate according to claim 4, comprising:
applying a gate signal to the first gate electrode of the thin film transistor and floating the second gate electrode during displaying a n^{th} frame of image, wherein n is a nonzero natural number; and
applying a gate signal to the second gate electrode of the thin film transistor and floating the first gate electrode during displaying a n+1^{th} frame of image.

17. An array substrate comprising the thin film transistor according to claim 2.

18. An array substrate comprising the thin film transistor according to claim 3.

19. A display device comprising the array substrate according to claim 17.

20. A display device comprising the array substrate according to claim 18.
